(19) United States
(12) Patent Application Publication
(10) Pub. No.: US 2025/0338390 A1
(43) Pub. Date: Oct. 30, 2025

(54) STIFFENER PLATES FOR ELECTRONIC COMPONENTS

(71) Applicants: Jain Raj Vettuvazhy Puthenpurayil, Bengaluru (IN); Hamid MohammadMirzaieDaryan, Toronto (CA); Ali Kalantarian, Richmond Hill (CA)

(72) Inventors: Jain Raj Vettuvazhy Puthenpurayil, Bengaluru (IN); Hamid MohammadMirzaieDaryan, Toronto (CA); Ali Kalantarian, Richmond Hill (CA)

(21) Appl. No.: 19/258,581

(22) Filed: Jul. 2, 2025

(51) Int. Cl. H05K 1/02; G06F 1/20; H05K 1/18; H05K 3/00

(52) U.S. Cl. CPC H05K 1/0204; G06F 1/206; H05K 1/181; H05K 3/00; H05K 2201/066

(57) ABSTRACT

Stiffener plates for electronic components are disclosed. An example stiffener plate for an electronic circuit board includes a body; and a first arm extending from the body, the first arm disposed at a first bend angle relative to the body, the first bend angle to change responsive to coupling of the first arm to the printed circuit board.

### BACKGROUND

A thermal interface material can be inserted between an electronic component such as a System on Chip (SoC) and a heat sink to facilitate transfer of heat from the electronic component to the heat sink for cooling of the electronic component. A stiffener plate is coupled to a surface of a printed circuit board (PCB) that supports the electronic component to increase rigidity of the PCB.

### BRIEF DESCRIPTION OF THE DRAWINGS

FIG. 1 is a partially exploded view of an example printed circuit board including electronic components and an example stiffener plate in accordance with teachings of this disclosure.

FIG. 2 is a side view of the example stiffener plate of FIG. 1.

FIG. 3 is an isometric view of the example stiffener plate of FIG. 1.

FIG. 4 illustrates assembly of the example printed circuit board and the example stiffener plate of FIG. 1 in a housing.

FIG. 5 is a schematic diagram of the example printed circuit board, an example electronic component, and the example stiffener plate of FIG. 1.

FIG. 6 is a flowchart of an example method of manufacturing the example stiffener plate of FIG. 1 in accordance with teachings of this disclosure.

FIG. 7 is a flowchart of an example method of coupling the example stiffener plate of FIG. 1 to a printed circuit board.

In general, the same reference numbers will be used throughout the drawing(s) and accompanying written description to refer to the same or like parts. The figures are not necessarily to scale. Instead, the thickness of the layers or regions may be enlarged in the drawings.

### DETAILED DESCRIPTION

A thermal interface material can be inserted between, for example, an electronic component such as a System on Chip (SoC) (e.g., a graphics processing unit (GPU)) and a heat sink to facilitate transfer of heat from the electronic component to the heat sink for cooling of the electronic component. The thermal interface material (TIM) can include, for example, a thermal adhesive material, a conductive pad including a material such as silicone, or other material to fill a gap or space between the electronic component and the heat sink. By filling the space between the electronic component and the heat sink, the TIM can reduce thermal resistance associated with the transfer of heat between the electronic component and the heat sink, thereby increasing cooling efficiency.

A thermal performance of the TIM in conducting heat is related to a bond line thickness of the TIM, or a distance occupied by the TIM between the electronic component (e.g., the SoC) and the heat sink. Forces exerted on the TIM by, for example, the heat sink, can cause the TIM to compress from an unloaded state. A thermal impedance, or resistance to heat flow, of the TIM typically decreases as the TIM is compressed. The TIM should be evenly compressed or substantially evenly compressed over an entire surface area of the TIM to achieve a target bond line thickness of the TIM that reduces (e.g., minimizes) thermal impedance while filling the gap between the electronic component and the heat sink. Such consistent and even compression can be obtained by applying a uniform pressure to the TIM.

In an electronic device such as a graphics card, pressure applied to the TIM can be affected by a stiffener plate, which is coupled to a printed circuit board (PCB) that supports the TIM. The stiffener plate can be coupled to a surface of the PCB opposite a surface to which the electronic component associated with the TIM is coupled to increase stiffness of the PCB, to prevent bending or twisting of the PCB, etc. The stiffener plate can be coupled to the PCB via mechanical fasteners such as screws. The fasteners can extend through the PCB and couple to, for example, a base of the heat sink. In some examples, the fasteners extend through the PCB and couple to a bolster plate to which the heat sink is also coupled. As the stiffener plate is coupled to the heat sink (or the bolster plate) via the mechanical fasteners extending through the PCB, forces are applied to the PCB and the heat sink (or the bolster plate). Accordingly, these forces are also applied to the electronic component(s) coupled to the PCB and corresponding TIMs in contact with the heat sink.

The pressure applied to the TIM can also be impacted by the spatial layout of electronic components on the PCB. For example, the TIM can be located over a SoC, which may be a GPU. Other electronic components such as memory devices and/or other MOSFET devices (e.g., for regulating voltage) can be located proximate to the SoC such that the heat sink extends over and, thus, exerts pressure on, the SoC and the other electronic components. Thermal pads or other TIMs can be located on the other electronic components (e.g., memory devices). Thus, the heat sink contacts the other electronic components (or the TIMs of the other electronic components) in addition to the TIM of the SoC. When the heat sink contacts the TIM of the SoC and the other electronic components (or the TIM(s) of the other electronic component(s)), the pressure applied by the heat sink to the TIM of the SoC may be unevenly distributed across the surface area of the TIM of the SoC based on the location(s) at which the heat sink contacts the other electronic components. For instance, if the memory devices are in an asymmetrical arrangement around the SoC such that all of the memory devices are located on one side of the SoC, a distribution of pressure across the TIM of the SoC by the heat sink can include first area(s) of lower pressure on the TIM and second area(s) of higher pressure on the TIM. The first area(s) of lower pressure correspond to portion(s) of the TIM that are proximate to the memory devices (e.g., portion(s) of the TIM at or near the side of the SoC on which the memory devices are located). Pressure of the heat sink on those portion(s) of the TIM of the SoC is affected (e.g., reduced) due to engagement of the heat sink with the memory devices. For instance, the heat sink may not contact a portion of the TIM of the SoC that is near the memory devices or may contact that portion of the TIM with less pressure because of the placement of the memory devices. However, the pressure distribution across the TIM of the SoC can include second area(s) of higher pressure corresponding to portion(s) of the TIM where pressure of the heat sink on the TIM is less affected by contact between heat sink and the memory devices (e.g., because the memory devices are farther away from those portion(s) of the TIM). The pressure differential across the surface area of TIM of the SoC due to asymmetrical arrangements of the components on the printed circuit board can be increased when a stiffener plate is coupled to heat sink via the PCB.

Uneven pressures applied to the TIM of the SoC (e.g., the GPU) results in uneven compression of the TIM and, thus, variability in the bond line thickness of the TIM across the SoC. Areas where lower pressure is exerted on the TIM can result in the formation of local hotspots at corresponding portions of the SoC because the thickness of the TIM is increased at those areas as compared to areas of the TIM where more compressive forces are applied on the TIM. Areas of increased thickness of the TIM are less efficient at removing heat because of increased thermal resistance. As discussed herein, thermal impedance of the TIM decreases with decreased bond line thickness of the TIM. Thus, variations in thickness of the TIM of the SoC can result in the formation of hotspots at area(s) where the TIM is less compressed (i.e., area(s) of great thickness) thereby leading to an increase in thermal impedance of the TIM. The creation of local hotspots can adversely affect thermal performance of, for example, a graphics card, by causing the GPU (e.g., the SoC) to implement thermal throttling sooner than the GPU would if the bond level thickness was consistent or substantially consistent across the TIM.

To facilitate even pressure distribution across the TIM of the SoC, some printed circuit board designs include symmetric or substantially symmetric arrangements of electronic components (e.g., memory devices, Voltage Regulator MOSFETs) about the SoC. For example, the same number of memory devices can be located on opposing sides of the SoC. However, in some instances, such spatial restrictions can limit compute performance of the electronic component(s) and, as a result, limit performance capabilities of a device including the electronic components.

Disclosed herein are example stiffener plates that facilitate the application of uniform pressure or substantially uniform pressure across a thermal interface material (TIM) of an electronic component such as a System on Chip (SoC). An example stiffener plate disclosed herein includes one or more arms that are bent relative to a body of the stiffener plate prior to coupling of the stiffener plate to a printed circuit board (PCB). The initial bend angle(s) of the arm(s) are selected based on locations of other electronic components, such as memory devices, on the PCB relative to the SoC. The stiffener plate is coupled to the heat sink (or to a bolster plate to which the heat sink is also coupled) via fasteners such as screws extending through openings in the arm(s) and the PCB. When the example stiffener plate is coupled to the heat sink (or the bolster plate) via the PCB, the arm(s) move from a first angular state (e.g., a bent state) to a second angular state (e.g., a straightened or substantially straightened state) such that ends of the arms of the stiffener plate are aligned with the plate body and rest against the surface of the PCB. The tightening of the fastener(s) against the initially bent arm(s) and resulting straightening of the arm(s) creates varying forces against the PCB and, thus, the heat sink. In particular, the varying force(s) created as a result of coupling the stiffener plate having the initially bent arm(s) to the heat sink via the PCB can provide for additional pressure on areas of the TIM of the SoC that would otherwise experience less pressure due to uneven pressure exerted by the heat sink because of the contact between the heat sink and other electronic components. As a result, example stiffener plates disclosed herein provide compensating forces that facilitate uniform pressure distribution or substantially uniform pressure distribution across the surface area of the TIM of the SoC. (In examples herein, references to “substantially uniform” in connection with pressure distribution across a surface account for variables that may arise during manufacturing of the electronic components and can affect pressure distribution, such as warpage at edge(s) of the SoC during a die casting manufacturing process.) The uniform or substantially uniform pressure applied across the TIM of the SoC enables a uniform or substantially uniform border line thickness to be achieved across the TIM of the SoC such that thermal impedance is reduced (e.g., minimized) and the formation of local hotspots at the SoC are reduced or prevented. As a result, example stiffener plates disclosed herein can provide for increased cooling capacity and enhanced thermal management of the electronic components.

Example stiffener plates disclosed herein facilitate uniform or substantially uniform pressure distribution at the TIM of the SoC regardless of contact between the heat sink and other electronic components that could otherwise lead to uneven compression of the TIM of the SoC. Therefore, example stiffener plates disclosed herein can be used with asymmetric arrangements of electronic components on the PCB relative to the SoC, such as when a plurality of memory devices are grouped on one side of the SoC. In examples disclosed herein, the initial bend angle(s) of the arm(s) of the stiffener plate arm(s) can be selected based on the locations of the SoC and the other electronic components that are to contact the heat sink on the PCB. Thus, examples disclosed herein enable flexible arrangements of electronic components on PCBs.

The pressure effects of the disclosed stiffener plates can provide for improved pressure distribution at other portions of the PCB and/or packages (e.g., a GPU package) coupled thereto. For example, solder balls can be used to provide contact with the PCB and a substrate of a GPU package. When the heat sink applies uneven pressure to the TIM of the SoC, the uneven pressure is also experienced by portion(s) of the SoC, portion(s) of the package substrate, the solder ball(s), etc. Such pressure differentials can degrade the components over time. When the disclosed stiffener plates are coupled to the PCB, the variable forces provided by tightening the fasteners extending through the stiffener plate arms, the PCB, and the heat sink (or the bolster plate to which the heat sink is also coupled) can collectively compensate for uneven pressure applied by the heat sink, thereby resulting in uniform or substantially uniform pressure being applied to the TIM as well as components such as the solder balls. As a result, example stiffener plates disclosed herein can increase mechanical reliability of the PCB and the components carried by the PCB.

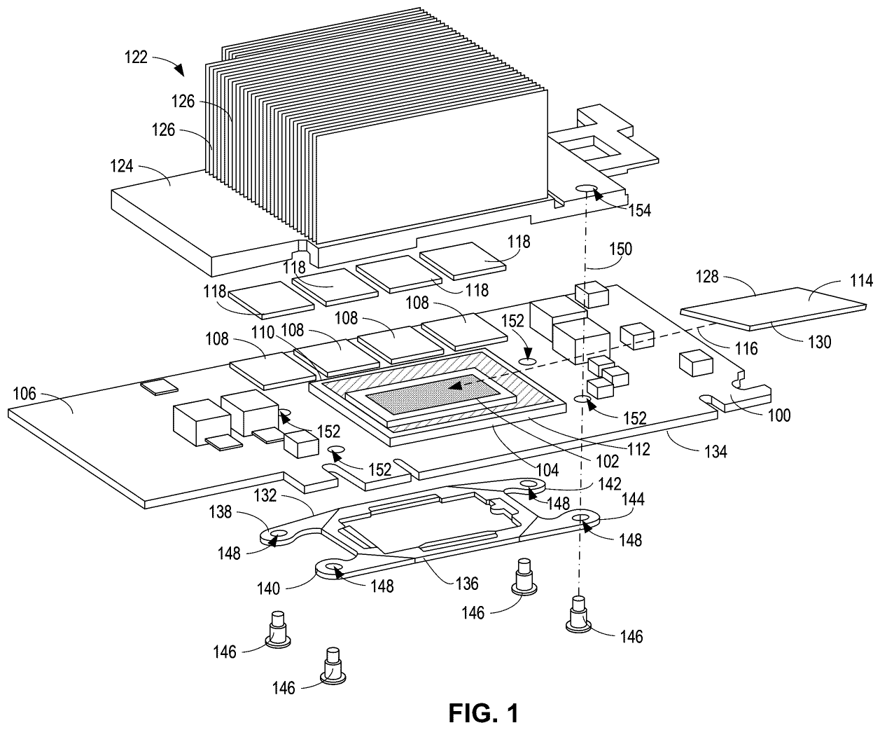

FIG. 1 is a partially exploded view of an example printed circuit board (PCB) 100 including electronic components coupled thereto. In the example of FIG. 1, the PCB 100 and the electronic components coupled thereto can form a graphics card. The electronic components include a System on Chip (SoC) 102 carried by a package substrate 104. The SoC 102 can be a graphics processing unit and the SoC 102 and the package substrate 104 can form a GPU package. The package substrate 104 is coupled to a first surface 106 of the PCB 100. In some examples, the package substrate 104 is carried by a bolster plate that is coupled to the first surface of the PCB 100. Also, a plurality of memory devices 108 are coupled to the first surface 106 of the PCB 100. As shown in FIG. 1, the memory devices 108 are located (e.g., grouped) on a first side 110 of the package substrate 104. In the example of FIG. 1, there are no memory devices on a second side 112 of the package substrate 104. Thus, the memory devices 108 are asymmetrically arranged relative to the SoC 102 in that the memory devices 108 are located on the same side 110 of the package substrate 104 (and, thus, the SoC 102). However, one or more of the memory devices 108 can be coupled to the first surface 106 of the PCB 100 at a different location(s) than shown in FIG. 1. Also, the PCB 100 can carry a different number of memory devices 108. Although the example PCB 100 of FIG. 1 carries other types of electronic components, such as MOSFETs, examples disclosed herein will primarily be discussed with respect to the SoC 102 and the memory devices 108.

In the example of FIG. 1, a thermal interface material (TIM) 114 extends over (e.g., above) the SoC 102, as represented by the arrowed line 116 in FIG. 1. In this example, the TIM 114 includes a thermally conductive material such as silicone in the form of a thermal pad. In other examples, the TIM 114 can be a paste or other adhesive. Also, a respective TIM 118 (e.g., a thermal pad) extends over each of the memory devices 108.

In the example of FIG. 1, a heat sink 122 is coupled to the PCB 100. The heat sink 122 includes a heat sink base 124 coupled to the first surface 106 of the PCB 100. In some examples, the heat sink base 124 coupled to a bolster plate and the bolster plate is coupled to the first surface 106 of the PCB 100. When assembled, the heat sink base 124 extends over the SoC 102 and the memory devices 108 such that the SoC 102, the package substrate 104, and the memory devices 108 are between the heat sink base 124 and the first surface 106 of the PCB 100. Heat generated by the SoC 102 is transferred to the heat sink 122 via the TIM 114 located between the SoC 102 and the heat sink base 124. Also, heat generated by the memory devices 108 is transferred to the heat sink 122 via the corresponding TIM 118 located between the respective memory devices 108 and the heat sink base 124. The heat moves from the heat sink base 124 to fins 126 of the heat sink 122. The heat is then transferred to air moving through the fins 126, thereby cooling the electronic components 102, 108 through the removal of heat. Although examples disclosed herein show the TIM 114 between (i.e., directly between) the SoC 102 and the heat sink base 124, in some examples, other components such as a heat spreader are between the SoC 102 and the heat sink base 124. In such examples, the TIM 114 may be located between the SoC 102 and the heat spreader and/or between the heat spreader and the heat sink base 124.

When the heat sink 122 is coupled to the PCB 100, the heat sink base 124 contacts at least a portion of the TIM 114 of the SoC and at least a portion of the TIMs 118 of the memory devices 108. As a result of this contact, the heat sink 122 applies pressure to the components located between the heat sink base 124 and the PCB 100. In the example of FIG. 1, the degree to which the heat sink base 124 is in contact with the TIM 114 varies across a surface area of the TIM 114 because of the grouping of the memory device 108 on the first side 110 of the PCB 100. As a result, pressure applied to the TIM 114 by the heat sink 122 varies across the TIM 114. For example, when assembled, a first edge 128 of the TIM 114 of the SoC 102 is closer to the memory devices 108 than a second edge 130 of the TIM 114. As such, when the heat sink base 124 is coupled to the PCB 100, the contact between the heat sink base 124 and the TIMs 118 of the memory devices 108 can affect the contact between the heat sink base 124 and portion(s) of the TIM 114 at or proximate to the first edge 128. In some examples, the pressure exerted by the heat sink 122 on portion(s) of the TIM 114 at or proximate to the first edge 128 may be less than the pressure exerted on portion(s) of the TIM 114 at or proximate to the second edge 130. In some examples, the heat sink base 124 may not contact portion(s) of the TIM 114 at or proximate to the first edge 128. Conversely, in this example, the heat sink 122 applies greater pressure to portion(s) of the TIM 114 at or proximate to the second edge 130 of the TIM 114 because there are no other electronic components on the second side 112 of the package substrate 104 to interfere with the contact between the TIM 114 and the heat sink base 124. Thus, the asymmetric arrangement of the memory devices 108 relative to the sides 110, 112 of the package substrate 104 results in uneven pressure distribution across the TIM 114. The uneven pressure distribution can also be transferred to components such as the SoC 102 and the package substrate 104.

The TIM 114 of the SoC 102 compresses due to the load from the heat sink 122, which decreases the bond line thickness between the SoC 102 and the heat sink base 124. As the TIM 114 compresses, thermal impedance of the TIM 114 decreases. However, the uneven application of pressure by the heat sink 122 across the TIM 114 due to the location of the memory devices 108 on the first side 110 of the package substrate 104 results in uneven compression of the TIM between the first and second edges 128, 130 of the TIM 114. As a result, bond line thickness and, thus, thermal impedance can vary across the TIM 114. For example, portion(s) of the TIM 114 proximate to the first edge 128 of the TIM 114 are subject to less pressure from the heat sink 122. Thus, there may be greater bond line thickness between the SoC 102 and the heat sink 122 at those portions as compared to the portion(s) of the TIM 114 proximate to the second edge 130, which is subject to more pressure from the heat sink 122. As a result, local hotspots may be more likely to form at portion(s) of the SoC 102 proximate to the first edge 128 of the TIM 114 as compared to portion(s) of the SoC 102 proximate to the second edge 130 of the TIM 114.

In the example of FIG. 1, a stiffener plate 132 is coupled to a second surface 134 of the PCB 100 that is opposite (e.g., below) the first surface 106. The example stiffener plate 132 of FIG. 1 includes a plate body 136 and four arms extending from the plate body 136, namely, a first arm 138, a second arm 140, a third arm 142, and a fourth arm 144. A shape and/or size of the stiffener plate 132, (including a shape and/or size of the plate body 136 and shapes and/or sizes of the arms 138, 140, 142, 144) can differ from the example shown in FIG. 1.

The stiffener plate 132 is coupled to the second surface 134 of the PCB 100 via mechanical fasteners 146 (e.g., screws) extending through respective openings 148 defined in the arms 138, 140, 142, 144. In the example of FIG. 1, the stiffener plate 132 couples to the heat sink 122 via the fasteners 146. As represented by line 150 in FIG. 1, a portion of a first one of the fasteners 146 extends through the opening 148 in the fourth arm 144, through an opening 152 defined in the PCB 100, and through an opening 154 defined in the heat sink base 124 of the heat sink 122. The other fasteners 146 extend through the respective openings 148 in the other arms 138, 140, 142 and through corresponding openings 152 in the PCB 100 to couple with respective portions of the heat sink base 124 (e.g., other openings defined in the heat sink base 124, not shown). In some examples, the fasteners 146 extend through the openings 152 in the PCB 100 to couple with a bolster plate on the first surface 106 of the PCB, where the heat sink base 124 is also coupled to the bolster plate. Thus, in such examples, the stiffener 132 plate is coupled (e.g., indirectly coupled) to the heat sink 122 via the bolster plate.

The stiffener plate 132 increases a strength and rigidity of the PCB 100 when, for example, the PCB 100 is in a housing or a chassis of an electronic device. In this example, the stiffener plate 132 also facilitates uniform pressure distribution or substantially uniform pressure distribution across the TIM 114 of the SoC 102 to counter the uneven pressure applied to the TIM 114 by the heat sink 122. As result, a bond line thickness of the TIM 114 across the SoC 102 can be consistent or substantially consistent, thereby providing for consistent or substantially consistent thermal impedance at the TIM 114 and reducing a thermal gradient across the SoC 102.

As disclosed herein, the example stiffener plate 132 of FIG. 1 is manufactured such that one or more of the arms 138, 140, 142, 144 is angled (e.g., bent) relative to the plate body 136 of the stiffener plate 132 prior to the coupling of the stiffener plate 132 to the heat sink base 124 via the second surface 134 of the PCB 100. During coupling of the stiffener plate 132 to the heat sink base 124 via the second surface 134 of the PCB 100, the arm(s) 138, 140, 142, 144 move such that the bend angle(s) of the arm(s) 138, 140, 142, 144 change. In particular, the arm(s) move 138, 140, 142, 144 from the initial bend angle toward a straight angle or a substantially straight angle relative to the plate body 136. When disposed at the straight angle or substantially straight angle relative to the plate body 136, the arms 138, 140, 142, 144 contact and lie flat or substantially flat against the second surface 134 of the PCB 100 along with the plate body 136. Due to the different initial bend angle(s) of the arm(s) 138, 140, 142, 144, different forces are generated when tightening the fasteners 146 at the arm(s) 138, 140, 142, 144 that have a greater bend angle relative to the plate body 136 as compared to the arm(s) 138, 140, 142, 144 that have a lesser bend angle. The summation of the varying forces generated when straightening or substantially straightening each arm 138, 140, 142, 144 via by tightening the fasteners 146 through the PCB 100 to couple the stiffener plate 132 to the heat sink 122 causes the distribution of pressure at the TIM 114 of the SoC 102 to change. For example, when the fasteners 146 are coupled to the heat sink base 124 via the stiffener plate 132, the fasteners 146 produce at least some loads that are imposed on the TIM 144 as the TIM 114 is sandwiched between the heat sink 122 and the stiffener plate 132. In particular, the varying forces generated via the extension of the fasteners 146 though the stiffener plate 132 facilitate adjustments to the pressure applied to the TIM 114 such that a uniform or substantially uniform pressure is applied across a surface area of the TIM 114. As result, the bond level thickness of the TIM 114 can change such that variations in bond level thickness across the TIM 114 are eliminated, substantially eliminated, or otherwise reduced.

For example, in FIG. 1, when the stiffener plate 132 is coupled to the PCB 100, the first arm 138 and the third arm 142 are located closer to the portion of the PCB 100 that includes the memory devices 108 than the second arm 140 and the fourth arm 144. In this example, the first arm 138 and the third arm 142 are formed with a first bend angle relative to the plate body 136 and the second arm 140 and the fourth arm 144 are formed with a second bend angle relative to the plate body 136 that is less than the first bend angle. The first and second bend angles can be selected based on the location of the memory devices 108 on the PCB 100 and the resulting variability in force applied by the heat sink 122 on portion(s) of the TIM 114 due to the asymmetric layout of the memory devices 108 relative to the package substrate 104 (and, thus, the SoC 102). As such, because the first arm 138 and the third arm 142 of the stiffener plate 132 are formed with the first or greater bend angle than the second bend angle of the second arm 140 and the fourth arm 144, more force is generated when straightening the first and third arms 138, 142 than the second and fourth arms 140, 144 during coupling of the stiffener plate 132 to the PCB 100 and the heat sink 122 via the fasteners 146. For example, during tightening of the fasteners 146 to the PCB 100, more compressive force is applied by the fasteners 146 extending through the openings 148 of the first and third arms 138, 142 to straighten and couple the first and third arms 138, 142 to the PCB 100 and the heat sink 122 than the fasteners 146 extending through the openings 148 of the second and fourth arms 140, 144 (e.g., because of the greater bend angle of the first and third arms 138, 142, which requires more forces to straighten). The increased forces produced as result of straightening the first and third arms 138, 142 compensates for the reduced compressive force applied by the heat 122 on the portion(s) of the TIM 114 at or proximate to the first edge 128 of the TIM 114. Also, because less force is used to couple the second and fourth arms 140, 144 of the stiffener plate 132 to the PCB 100, the forces on the TIM 114 at or proximate to the second edge 130 of the TIM 114 do not increase or substantially increase. Therefore, the stiffener plate 132 addresses the pressure differential across the TIM 114 via the selective angling of the arm(s) 138, 140, 142, 144 and the collective forces generated via the straightening of the bent arm(s) 138 138, 140, 142, 144. As result of the compensating forces provided by the stiffener plate 132, the variability in the pressure distribution across the TIM 114 of the SoC is reduced or substantially eliminated such that uniform or substantially uniform pressure is applied to the TIM 114.

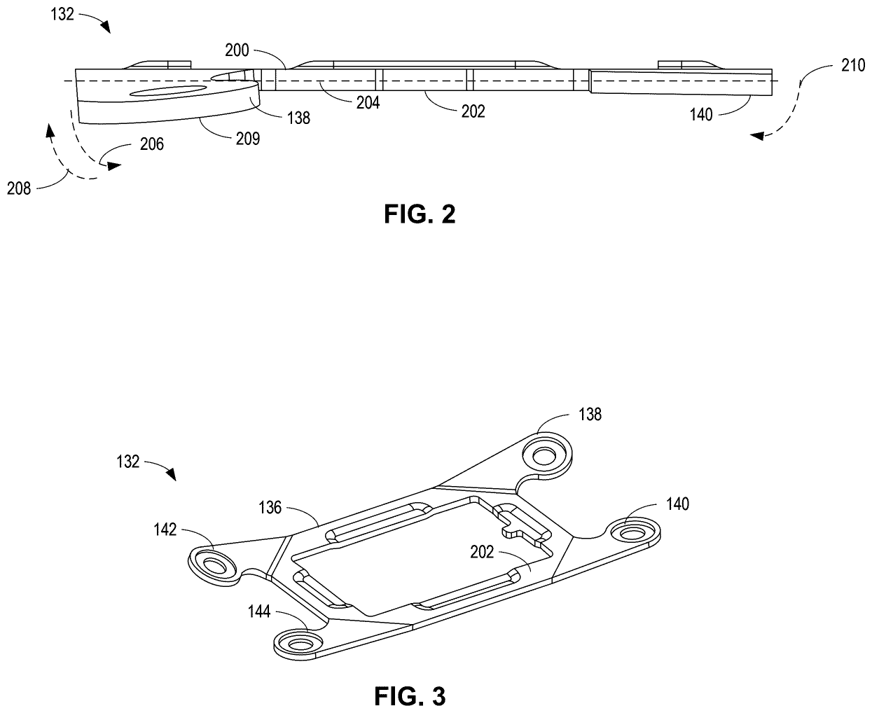

FIG. 2 is a side view of the example stiffener plate 132 of FIG. 1. FIG. 2 shows portions of the plate body 136, the first arm 138, and the second arm 140 before the stiffener plate 132 is coupled to the PCB 100 of FIG. 1. The plate body 136 has a first surface 200 and a second, opposing surface 202. As represented by line 204 in FIG. 2, an axis (e.g., a lateral axis) passes through a portion of the plate body 136. The first arm 138 is disposed at a first bend angle relative to the axis 204, as represented by arrow 206 in FIG. 2. Put another away, the first arm 138 is bent in a direction toward the second surface 202 of the plate body 136 when the first arm 138 is at the first bend angle (e.g., a first angular state). The first bend angle of the first arm 138 can be, for example, 7°. However, the first bend angle can be larger or smaller based on the location of the electronic components on the PCB 100 and the compensating forces to be provided via the stiffener plate arms 138, 140, 142, 144 to address pressure differentials across the TIM 114 of the SoC 102 (FIG. 1). When the stiffener plate 132 is coupled to the PCB 100 and the heat sink 122 via the fastener 146 extending through the opening 148 in the first arm 138, the tightening forces applied to the fastener 146 cause the first arm 138 to move in a direction toward the first surface 200 of the plate body 136, as represented by arrow 208 in FIG. 2. Thus, the bend angle of the first arm 138 changes (e.g., to a second angular state) and moves to a second angle (e.g., a second angular state). The second angle can correspond to a straight angle or a substantially straight angle relative to the plate body 136. Put another way, the first arm 138 is straightened or substantially straightened relative to the plate body 136 due to tightening forces applied to the fastener 146 when coupling the stiffener plate 132 to the PCB 100. For example, when the first arm 138 is coupled to the PCB 100 and the heat sink 122 via the fastener 146, an end 209 of the first arm 138 may be aligned or substantially aligned with the plate body 136 such that a plane passes through the plate body 136 and the end 209 of the stiffener plate 132.

The second arm 140 of the example stiffener plate 132 is at a second bend angle relative to the axis 204, as represented by arrow 210 in FIG. 2. As disclosed in connection with FIG. 1, the second bend angle is less than the first bend angle based on the location of the memory devices 108 on the PCB 100 (FIG. 1). For example, the second bend angle can be 1°. However, the second bend angle can have different values. In some examples, the second bend angle can be greater than the first bend angle if the memory devices 108 are located on a different side of the package substrate 104 than shown in the example of FIG. 1. For example, if all of the memory devices 108 were located on the opposite side 112 of the package substrate 104 from the side 110, then the bend angle of the second arm 140 may be greater than the bend angle of first arm 138 so that greater compensating forces are generated via the second arm 140 than the first arm 138 as a result of coupling of the stiffener plate 132 to the PCB 100.

FIG. 3 is an isometric view of the example stiffener plate 132 of FIG. 1. In particular, FIG. 3 shows the second surface 202 of the plate body 136, which is the surface toward which the arm(s) 138, 140, 142, 144 are bent prior to being coupled to the PCB 100 and the heat sink 122 (FIG. 1). In examples disclosed herein, the bend angle of each arm 138, 140, 142, 144 relative to the plate body 136 (e.g., relative to the axis 204 of FIG. 2 extending through the plate body 136) can be selected based on the collective forces to be generated by the stiffener plate 132 to compensate for uneven pressure distribution across the TIM 114 of the SoC 102 by the heat sink 122 due to, for example, asymmetric layouts of components on the PCB 100. In some examples, each of the arms 138, 140, 142, 144 can have a different bend angle prior to coupling the stiffener plate 132 to the PCB 100. In some examples, one or more of the arms 138, 140, 142, 144 is not bent relative to the plate body 136 (that is, in some examples, the bend angle is 0°).

The bend angle of the respective arms 138, 140, 142, 144 can be selected by performing force analysis simulations based on a layout of the components on the PCB 100 to which the stiffener plate 132 is to be coupled. The simulations can be used to determine the force to be applied via each arm 138, 140, 142, 144 of the stiffener plate 132. In particular, the simulations can determine the forces based on factors such as locations of the SoC 102 and other electronic components 108 on the PCB 100; contact points of the heat sink base 124 with the PCB components 102, 108; material properties of the TIM(s) 114, 118; a target bond line thickness value to fill a gap between the SoC 102 and the heat sink base 124 while reducing (e.g., minimizing) thermal impedance; a material of the stiffener plate 132, etc. During manufacture, the bend angle(s) of the arm(s) 138, 140, 142, 144 can be formed via bending processes such as press brakes that use a punch and die to deform the material of the stiffener plate.

In some examples, a material of the stiffener plate 132 is selected based on the forces to be generated via the straightening or substantial straightening of the bent the arm(s) 138, 140, 142, 144 and properties of the material. In examples in which the bend angles of the arm(s) 138, 140, 142, 144 are to be, for instance, less than 10°, then a flexible material such as a plastic may be used for the stiffener plate 132. In examples in which the bend angles of the arm(s) 138, 140, 142, 144 are to be greater than, for instance, 10°, then a malleable material with increased strength may be used so that the material withstands the formation of the bend angles and the subsequent straightening of the arm(s) 138, 140, 142, 144 during coupling of the stiffener plate 132 to the PCB 100 and contributes to the generation of the compensating forces. For example, the material can include a metal such as steel.

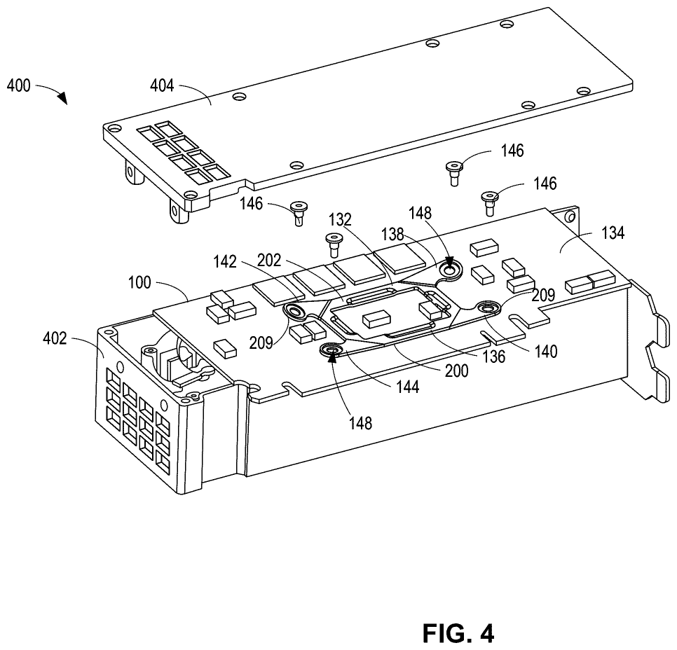

FIG. 4 illustrates assembly of the PCB 100 and the stiffener plate 132 in a housing 400 defined by a shroud 402 and a backplate 404. In the example of FIG. 4, electronic components are coupled to the second surface 134 of the PCB 100. However, in some examples, the second surface 134 of the PCB 100 does not include electronic components coupled thereto. As shown in FIG. 4, during assembly, the stiffener plate 132 is placed on the second surface 134 such that the first surface 200 of the plate body 136 contacts the second surface 134 of the PCB 100. Thus, as shown in FIG. 4, the arm(s) 138, 140, 142, 144 of the stiffener plate 132 are at least partially spaced apart from the second surface 134 of the PCB 100 due to the bend angle(s) of the arm(s) 138, 140, 142, 144. Put another way, prior to fastening the stiffener plate 132 to the PCB 100, at least a portion of the arm(s) 138, 140, 142, 144 (e.g., the ends 209 of the arms) is elevated or not in contact with the second surface 134 of the PCB 100 due to the respective arm bend angle(s), which causes the arm(s) 138, 140, 142, 144 to be bent away from the first surface 200 of the stiffener plate 132 and toward the second surface 202 of the stiffener plate 132.

As discussed herein, respective fasteners 146 extend through the corresponding openings 148 in the arms 138, 140, 142, 144 of the stiffener plate 132, the corresponding openings 152 in the PCB 100, and openings (e.g., the opening 154 of FIG. 1) in the heat sink base 124 of the heat sink 122. As the fasteners 146 are tightened to the PCB 100 and the heat sink 122, the arms 138, 140, 142, 144 move from a first angle/first angular state (e.g., an initial bend angle or a bent state) to a second angle/second angular state (e.g., a straight or substantially straight angle) as the fasteners 146 extend into the PCB 100 and the heat sink base 124 via the openings 148 in the arms 138, 140, 142, 144. When the arms 138, 140, 142, 144 are at the second angle (e.g., the straight or substantially straight angle), ends 209 of the arms 138, 140, 142, 144 are no longer elevated relative to the PCB 100 but, instead, contact the second surface 134 of the PCB 100. In some examples, the ends 209 of the arms 138, 140, 142, 144 lie in a same plane as the plate body 136 when the arms 138, 140, 142, 144 are in the second angular state (e.g., straightened). Straightening each of the arms 138, 140, 142, 144 generates a force based on the respective bend angle of the arm 138, 140, 142, 144. Larger bend angles are associated with greater forces generated to straighten or substantially the arm 138, 140, 142, 144. The variable forces generated based on the different bend angles of the arms 138, 140, 142, 144 can collectively compensate for uneven pressures applied by the heat sink 122 on the components such as the SoC 102 and the TIM 114 on the opposing side of the PCB 100. The forces generated as a result of coupling of the stiffener plate 132 to the PCB 100 and the heat sink 122 can be transferred to the components of the PCB 100 to cause pressure applied to the components (e.g., the TIM 114) to be adjusted.

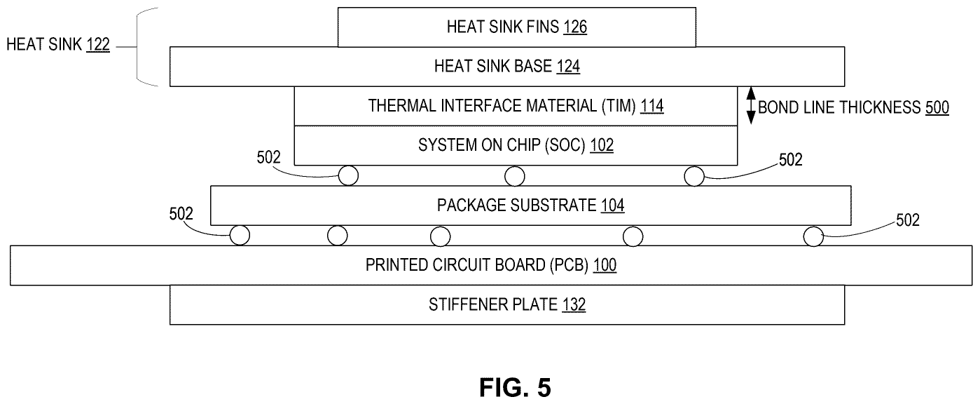

FIG. 5 is a schematic view of the example printed circuit board 100 of FIG. 1, the SoC 102 coupled to the printed circuit board 100 via the package substrate 104, and the example stiffener plate 132 of FIG. 1. In some examples, a bolster plate is between the PCB 100 and the package substrate 104. In some examples, a heat spreader is between the heat sink 122 and the SoC 102 and the TIM 114 is between the Soc 102 and the heat spreader and/or between the heat spreader and the heat sink base 124.

As represented by arrow 500 in FIG. 5, the TIM 114 has a bond line thickness corresponding to the thickness of the TIM 114 between the SoC 102 and the heat sink base 124 of the heat sink 122. The bond line thickness can change as the TIM 114 is compressed by the load from the heat sink 122. As disclosed herein, in some examples, the bond line thickness can vary across the TIM 114 due to uneven pressure applied by heat sink 122 when the heat sink base 124 is in contact with other components on the PCB 100 (e.g., the memory devices 108) that asymmetrically arranged relative to the SoC 102. Variations in the bond line thickness can result in inconsistent thermal impedance at the TIM 114 and, thus, areas of increased heat transfer resistance at the TIM 114.

As disclosed herein, the stiffener plate 132 can compensate for the uneven pressure applied by the heat sink 122 via selective angling or bending of the arms 138, 140, 142, 144 (FIG. 1) of the stiffener plate 132 prior to coupling the stiffener plate 132 to the PCB 100 and the heat sink base 124 via the fasteners 146 (FIG. 1). As a result of the compensating forces generated via the stiffener plate 132 and the fasteners 146 extending therethrough, pressure across the TIM 114 can become uniform or substantially uniform, thereby facilitating a consistent bond line thickness across the TIM 114.

In the example of FIG. 5, solder balls 502 are located between the PCB 100 and the package substrate 104, some of which are illustrated in FIG. 5. Also, solder balls 502 are located between the SoC 102 and the package substrate 104, some of which are illustrated in FIG. 5. The solder balls 502 facilitate electrical contact between the PCB 100 and the SoC 102. When the heat sink 122 exerts pressure on the SoC 102 and the package substrate 104, the solder balls 502 are also subject to the pressure, including any variations or unevenness in the pressure applied by the heat sink 122 at the SoC 102. The non-uniform pressure on the solder balls 502 can cause certain solder balls 502 to degrade, which can adversely impact the mechanical stability of the package (e.g., a GPU package) formed by the SoC 102 and the package substrate 104. In examples disclosed herein, the forces generated by the coupling of the stiffener plate 132 to the PCB 100 and the heat sink 122 can provide for uniform pressure or substantially uniform pressure to be applied to the solder balls 502 in addition adjusting pressures applied at the TIM 114 (and, thus, the SoC 102 and the package substrate 104). Therefore, the example stiffener plate 132 enhances mechanical integrity of the package coupled to the PCB 100.

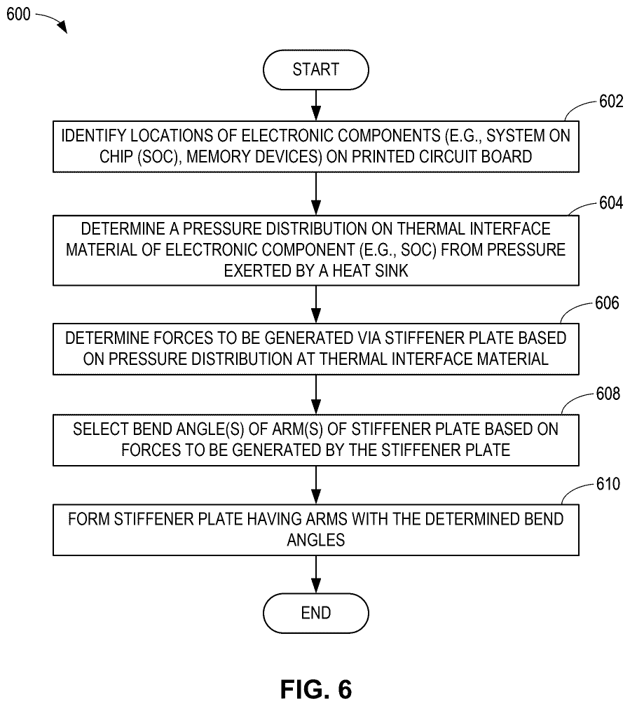

FIG. 6 is a flowchart of an example method 600 of manufacturing the example stiffener plate 132 of FIG. 1. One or more elements of FIG. 6 can be performed based on, for example, simulations generated using force analysis software installed on a computer.

At block 602, the example method 600 includes identifying locations of electronic components such as the SoC 102 and the memory devices 108 on the PCB 100 to detect, for example, asymmetric arrangements of the components on the PCB 100 relative to the SoC 102 that can affect pressure applied by the heat sink 122 on the TIM 114 of the SoC 102. At block 604, the example method 600 includes determining a pressure distribution on the TIM 114 of the SoC 102 due to pressure exerted by the heat sink 122. As disclosed herein, an uneven pressure distribution across the surface area of the TIM 114 can result in variability of bond line thickness of the TIM 114 and thus, variability in thermal impedance at the TIM 114.

At block 606, the example method 600 includes determining forces to be generated by the stiffener plate 132 via coupling of the stiffener plate 132 to the PCB 100 and the heat sink 122 to compensate for the uneven pressure distribution across the TIM 114 of the Soc 102. For example, simulations can be performed to identify the force values that collectively lead to uniform or substantially uniform compression of the TIM 114 to achieve target or prescribed bond line thickness of the TIM 114. The simulations can be performed for different materials of the stiffener plate 132 and the resulting forces generated based on the material properties.

At block 608, the example method 600 includes selecting the bend angle(s) of the arm(s) 138, 140, 142, 144 of the stiffener plate 132 based on the forces to be generated via the coupling of the arm 138, 140, 142, 144 to the PCB 100. Simulations can be performed with the arms 138, 140, 142, 144 at different bend angles to identify the bend angle(s) of the arm(s) 138, 140, 142, 144 that will provide the compensating forces based on, for example, material properties of the stiffener plate 132.

At block 610, the example method 600 includes forming the stiffener plate 132 with the arm(s) 138, 140, 142, 144 at the respective bend angles such that the compensating forces are generated when the stiffener plate 132 is coupled to the PCB 100 and the heat sink 122. For example, manufacturing processes such as punch and die processes can be used to bend the arm(s) 138, 140, 142, 144.

While an example manner of manufacturing the stiffener plate 132 is illustrated in FIG. 6, one or more of the elements, processes and/or devices illustrated in FIG. 6 may be combined, divided, re-arranged, omitted, eliminated, and/or implemented in any other way.

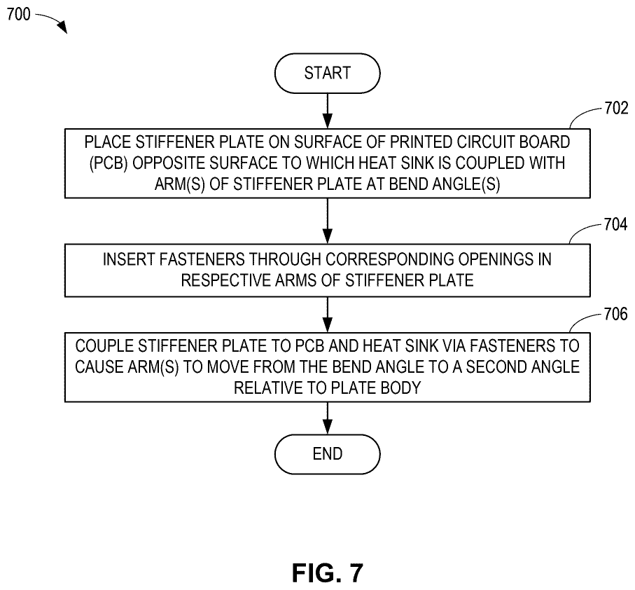

FIG. 7 is a flowchart of an example method 700 for coupling the example stiffener plate 132 of FIG. 1 to the PCB 100 of FIG. 1. At block 702, the example method 700 includes placing the stiffener plate 132 on the second surface 134 of the PCB 100 (i.e., the surface opposite the first surface 106 to which the heat sink 122 is coupled). When the stiffener plate 132 is on the second surface 134 of the PCB 100 and prior to coupling the stiffener plate 132 to the PCB 100, the arm(s) 138, 140, 142, 144 are at a bend angle (e.g., an initial bend angle) relative to the plate body 136 of the stiffener plate 132. For example, the end(s) 209 of arm(s) 138, 140, 142, 144 may be elevated relative to the second surface 134 of the PCB 100 on which the plate body 136 rests due to the bend angle(s).

At block 704, the example method 700 includes inserting the fasteners 146 through the corresponding openings 148 in the arms 138, 140, 142, 144 of the stiffener plate 132.

At block 706, the example method 700 includes coupling the stiffener plate 132 to the PCB 100 and the heat sink 122 via the fasteners 146 to cause the arm(s) 138, 140, 142, 144 to move from the bend angle(s) to a second angle (e.g., a straight or substantially straight angle) relative to the plate body 136. As disclosed herein, forces generated as a result of coupling the stiffener plate 132 to the PCB 100 and the heat sink 122 (e.g., via straightening the arm(s) 138, 140, 142, 144) can compensate for uneven pressure distributions across the TIM 114 at the first surface 106 of the PCB 100.

While an example manner of coupling the example stiffener plate 132 of FIG. 1 to the PCB 100 is illustrated in FIG. 7, one or more of the elements, processes and/or devices illustrated in FIG. 7 may be combined, divided, re-arranged, omitted, eliminated, and/or implemented in any other way

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

From the foregoing, it will be appreciated that example systems, apparatus, articles of manufacture, and methods have been disclosed that provide for enhanced thermal management of electronic components using stiffener plates. Example stiffener plates disclosed herein include arms that are manufactured at initial bend angles prior to coupling the stiffener plate to a printed circuit board (PCB). When the stiffener plate is coupled to a heat sink on the PCB, the arms move from the bent state to a straightened or substantially straightened state. Variable forces generated during the straightening of the arms from their respective bend angles can compensate for uneven pressure applied by the heat sink to a thermal interface material of an electronic component, such as a system-on-chip, as well as uneven pressures applied to other PCB components such as solder balls. Thus, example stiffener plates disclosed herein can improve thermal management of electronic components by facilitating uniform or substantially uniform pressure across a thermal interface material, which reduces variability in thermal impedance that can lead to localized hotspots at the electronic component. Example stiffener plates disclosed herein also increase mechanical reliability of the PCB and the components coupled thereto in examples in which components on the PCB are asymmetrically arranged.

Example stiffener plates for electronic components are disclosed. Further examples and combinations thereof include the following:

Example 1 includes a stiffener plate for a printed circuit board, the stiffener plate including a body; and a first arm extending from the body, the first arm disposed at a first bend angle relative to the body, the first bend angle to change responsive to coupling of the first arm to the printed circuit board.

Example 2 includes any preceding clause(s) of Example 1, further including a second arm extending from the body, the second arm disposed at a second bend angle relative to the body, the second bend angle different than the first bend angle, the second bend angle to change responsive to coupling of the second arm to the printed circuit board.

Example 3 includes any preceding clause(s) of any one or more of Examples 1-2, further including a third arm extending from the body, the third arm disposed at the first bend angle, the second bend angle, or a third bend angle relative to the body, the third bend angle different than the first bend angle and the second bend angle.

Example 4 includes any preceding clause(s) of any one or more of Examples 1-3 includes any preceding clause(s) of any one or more of Examples 1-3, further including a fourth arm extending from the body.

Example 5 includes any preceding clause(s) of any one or more of Examples 1-4, wherein the first arm includes a first opening defined therein, the first opening to receive a fastener to couple the first arm to the printed circuit board.

Example 6 includes any preceding clause(s) of any one or more of Examples 1-5, wherein the first arm is movable from the first bend angle to an angle in which an end of the first arm is aligned with the body.

Example 8 includes a system including a printed circuit board having a first surface and a second surface opposite the first surface; a first electronic component coupled to the first surface of the printed circuit board; a thermal interface material extending over the first electronic component; a heat sink coupled to the first surface of the printed circuit board, the heat sink to apply pressure to the thermal interface material; and a stiffener plate to be coupled to the heat sink via the second surface of the printed circuit board, the stiffener plate having a body and an arm extending from the body, the arm movable from a first angle to a second angle relative to the body responsive to coupling of the stiffener plate to the heat sink to change a distribution of pressure at the thermal interface material.

Example 8 includes any preceding clause(s) of Example 7, wherein the first angle of the arm corresponds to a first bend angle, the stiffener plate having a second arm extending from the body, the second arm disposed at a second bend angle, the second bend angle different than the first bend angle.

Example 9 includes any preceding clause(s) of any one or more of Examples 7-8, wherein the body of the stiffener plate has a first surface and a second surface opposite the first surface, the first surface of the stiffener plate to contact the second surface of the printed circuit board, the arm bent toward the second surface of the stiffener plate when the arm is at the first angle.

Example 10 includes any preceding clause(s) of any one or more of Examples 7-9, wherein the arm includes an opening defined therein, the stiffener plate to be coupled to the second surface of the printed circuit board via a fastener extending through the opening.

Example 11 includes any preceding clause(s) of any one or more of Examples 7-10, wherein the first electronic component is a graphics processing unit.

Example 12 includes any preceding clause(s) of any one or more of Examples 7-11, further including a plurality of second electronic components coupled to the first surface of the printed circuit board, the plurality of second electronic components arranged asymmetrically relative to the first electronic component.

Example 13 includes any preceding clause(s) of any one or more of Examples 7-12, wherein the change in the distribution of pressure at the thermal interface material is to cause a bond level thickness of at least a portion of the thermal interface material to change.

Example 14 includes graphics card including a printed circuit board having a first electronic component and a plurality of second electronic components coupled thereto, respective ones of the second electronic components arranged asymmetrically relative to the first electronic component; a heat sink; a thermal interface material between the first electronic component and the heat sink, the heat sink to apply pressure to the thermal interface material; and a stiffener plate having an arm, the arm coupled to the printed circuit board via a fastener, the arm movable from a first angular state to a second angular state relative to a body of the stiffener plate during coupling of the arm to the printed circuit board, the movement of the arm to cause the pressure applied to the thermal interface material to be adjusted.

Example 15 includes any preceding clause(s) of Example 14, wherein the first electronic component is a graphic processing unit and the second electronic components are memory devices.

Example 16 includes any preceding clause(s) of any one or more of Examples 14-15, wherein the arm has a first bend angle relative to the body of the stiffener plate when the arm is in the first angular state.

Example 17 includes any preceding clause(s) of any one or more of Examples 14-16, wherein the arm is a first arm and the stiffener plate includes a second arm, the second arm having a second bend angle to the body of the stiffener plate when the arm is in the first angular state, the second bend angle different than the first bend angle.

Example 18 includes any preceding clause(s) of any one or more of Examples 14-17, wherein the first electronic component is coupled to a package substrate and each of the second electronic components is arranged on a first side of the package substrate.

Example 19 includes any preceding clause(s) of any one or more of Examples 14-18, further including a solder ball disposed between the first electronic component and the printed circuit board, the coupling of the arm to the printed circuit board to affect pressure applied to the solder ball.

Example 20 includes any preceding clause(s) of any one or more of Examples 14-19, wherein the fastener is coupled to the heat sink.

Example 21 includes a method including placing a first surface of a stiffener plate on a first surface of a printed circuit board, a heat sink coupled to a second surface of the printed circuit board opposite the first surface, the stiffener plate having an arm disposed at a bend angle relative to a body of the stiffener plate prior to the stiffener plate being coupled to the printed circuit board, at least a portion of the arm elevated relative to the first surface of the printed circuit board when the first surface of the stiffener plate is in contact with the first surface of printed circuit board prior to the stiffener plate being coupled to the printed circuit board; inserting a fastener through an opening in the arm of the stiffener plate and an opening in the printed circuit board; and coupling the stiffener plate to the heat sink via the fastener to cause the bend angle of the arm to change.

Example 22 includes any preceding clause(s) of Example 21, wherein coupling the stiffener plate to the heat sink includes tightening the fastener to the first surface of the printed circuit board.

Example 23 includes a method including identifying locations of respective electronic components on a printed circuit board; determining a pressure distribution at a thermal interface material based on pressure exerted by a heat sink on the thermal interface material; and selecting a bend angle of an arm of a stiffener plate based on the pressure distribution.

Example 24 includes any preceding clause(s) of Example 23, wherein the arm is a first arm, the bend angle is a first bend angle, and further including selecting a second bend angle of a second arm of the stiffener plate based on the pressure distribution, the second bend angle different than the first bend angle.

Example 25 includes any preceding clause(s) of Examples 23-24, further including determining a force to be generated via the stiffener plate based on a material of the stiffener plate.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

1. A stiffener plate for a printed circuit board, the stiffener plate comprising:
a body; and
a first arm extending from the body, the first arm disposed at a first bend angle relative to the body, the first bend angle to change responsive to coupling of the first arm to the printed circuit board.

2. The stiffener plate of claim 1, further including a second arm extending from the body, the second arm disposed at a second bend angle relative to the body, the second bend angle different than the first bend angle, the second bend angle to change responsive to coupling of the second arm to the printed circuit board.

3. The stiffener plate of claim 2, further including a third arm extending from the body, the third arm disposed at the first bend angle, the second bend angle, or a third bend angle relative to the body, the third bend angle different than the first bend angle and the second bend angle.

4. The stiffener plate of claim 3, further including a fourth arm extending from the body.

5. The stiffener plate of claim 1, wherein the first arm includes a first opening defined therein, the first opening to receive a fastener to couple the first arm to the printed circuit board.

6. The stiffener plate of claim 1, wherein the first arm is movable from the first bend angle to an angle in which an end of the first arm is aligned with the body.

7. A system comprising:
a printed circuit board having a first surface and a second surface opposite the first surface;
a first electronic component coupled to the first surface of the printed circuit board;
a thermal interface material extending over the first electronic component;
a heat sink coupled to the first surface of the printed circuit board, the heat sink to apply pressure to the thermal interface material; and
a stiffener plate to be coupled to the heat sink via the second surface of the printed circuit board, the stiffener plate having a body and an arm extending from the body, the arm movable from a first angle to a second angle relative to the body responsive to coupling of the stiffener plate to the heat sink to change a distribution of pressure at the thermal interface material.

8. The system of claim 7, wherein the first angle of the arm corresponds to a first bend angle, the stiffener plate having a second arm extending from the body, the second arm disposed at a second bend angle, the second bend angle different than the first bend angle.

9. The system of claim 7, wherein the body of the stiffener plate has a first surface and a second surface opposite the first surface, the first surface of the stiffener plate to contact the second surface of the printed circuit board, the arm bent toward the second surface of the stiffener plate when the arm is at the first angle.

10. The system of claim 7, wherein the arm includes an opening defined therein, the stiffener plate to be coupled to the second surface of the printed circuit board via a fastener extending through the opening.

11. The system of claim 7, wherein the first electronic component is a graphics processing unit.

12. The system of claim 7, further including a plurality of second electronic components coupled to the first surface of the printed circuit board, the plurality of second electronic components arranged asymmetrically relative to the first electronic component.

13. The system of claim 7, wherein the change in the distribution of pressure at the thermal interface material is to cause a bond level thickness of at least a portion of the thermal interface material to change.

14. A graphics card comprising:
a printed circuit board having a first electronic component and a plurality of second electronic components coupled thereto, respective ones of the second electronic components arranged asymmetrically relative to the first electronic component;
a heat sink;
a thermal interface material between the first electronic component and the heat sink, the heat sink to apply pressure to the thermal interface material; and
a stiffener plate having an arm, the arm coupled to the printed circuit board via a fastener, the arm movable from a first angular state to a second angular state relative to a body of the stiffener plate during coupling of the arm to the printed circuit board, the movement of the arm to cause the pressure applied to the thermal interface material to be adjusted.

15. The graphics card of claim 14, wherein the first electronic component is a graphic processing unit and the second electronic components are memory devices.

16. The graphics card of claim 14, wherein the arm has a first bend angle relative to the body of the stiffener plate when the arm is in the first angular state.

17. The graphics card of claim 16, wherein the arm is a first arm and the stiffener plate includes a second arm, the second arm having a second bend angle to the body of the stiffener plate when the arm is in the first angular state, the second bend angle different than the first bend angle.

18. The graphics card of claim 14, wherein the first electronic component is coupled to a package substrate and each of the second electronic components is arranged on a first side of the package substrate.

19. The graphics card of claim 14, further including a solder ball disposed between the first electronic component and the printed circuit board, the coupling of the arm to the printed circuit board to affect pressure applied to the solder ball.

20. The graphics card of claim 14, wherein the fastener is coupled to the heat sink.

21.-25. (canceled)
